(19) United States
(12) Patent Application Publication
(10) Pub. No.: US 2019/0218660 A1
(43) Pub. Date: Jul. 18, 2019

(54) DEGASSING METHOD, DEGASSING CHAMBER, AND SEMICONDUCTOR PROCESSING APPARATUS

(71) Applicant: BEIJING NAURA MICROELECTRONICS EQUIPMENT CO., LTD., Beijing (CN)

(72) Inventors: Hua YE, Beijing (CN); Qiang JIA, Beijing (CN); Yue XU, Beijing (CN); Bingxuan JIANG, Beijing (CN); Jue HOU, Beijing (CN); Pu SHI, Beijing (CN); Jinguo ZHENG, Beijing (CN); Lingbei ZONG, Beijing (CN); Mengxin ZHAO, Beijing (CN); Peijun DING, Beijing (CN); Hougong WANG, Beijing (CN)

(21) Appl. No.: 16/366,392

(22) Filed: Mar. 27, 2019

Related U.S. Application Data
(63) Continuation of application No. PCT/CN2017/075973, filed on Mar. 8, 2017.

(30) Foreign Application Priority Data
Sep. 27, 2016 (CN) 201610854815.5

(51) Int. Cl. C23C 14/56; F26B 3/30; F26B 5/04

(52) U.S. Cl. CPC C23C 14/564; H01L 21/02063; F26B 5/042; F26B 3/30

(57) ABSTRACT

The present disclosure provides a degassing method, a degassing chamber, and a semiconductor processing apparatus. The degassing method includes heating a degassing chamber to provide an internal temperature at a preset temperature, and maintaining the internal temperature of the degassing chamber at the preset temperature; and transferring substrates to be degassed into the degassing chamber and heating the substrates for a preset period of time, and taking the substrates out after the preset period of time of the heating. The disclosed degassing method is able to improve the temperature uniformity not only for a same batch of substrates but also for different batches of substrates. In addition, the disclosed degassing method can also realize anytime instant loading/unloading of the substrates to be degassed, thereby increasing the productivity of the equipment.

### CROSS-REFERENCES TO RELATED APPLICATIONS

This application is a continuation application of International Application No. PCT/CN2017/075973, filed on Mar. 8, 2017, which claims the priority and benefits of Chinese Patent Application Serial No. CN201610854815.5, filed with the State Intellectual Property Office of P. R. China on Sep. 27, 2016, the entire content of all of which is incorporated herein by reference.

### FIELD OF THE DISCLOSURE

The present disclosure generally relates to the field of semiconductor device fabrication technology and, more particularly, relates to a degassing method, a degassing chamber, and a semiconductor processing apparatus.

### BACKGROUND

Physical vapor deposition (PVD) technology is widely used in the field of semiconductor manufacturing technology. In a PVD process, a degas step is usually required to remove impurities, e.g. water vapor, adsorbed on the substrate from the atmosphere, and clean the surface of the substrate. As such, the substrate provided for subsequent processes can be as clean as possible. For example, as shown in FIG. 1, the process flow of a PVD process for copper interconnections includes such a degas step.

The degassing chambers used for degassing can be divided into two types: single-substrate degassing chamber and multiple-substrate degassing chamber. Between these two types of degassing chambers, the multiple-substrate degassing chamber has been used more and more often due to its capability of simultaneously heating multiple substrates and its high productivity feature. For a multiple-substrate degassing chamber, before performing the degassing process, a substrate container in the housing is first lowered to a designated loading/unloading position, and substrates are transferred into the substrate container sequentially through a vacuum manipulator until the substrate container is filled with substrates. Then, the substrate container is raised to a designated heating position. When the process starts, a bulb is used to rapidly heat the substrates in the substrate container for a certain period of time until the substrates reach the temperature required for the process. After the process is finished, the vacuum manipulator sequentially transfers the substrates out from the housing, and then repeats the above heating process by placing the next batch of substrates to be heated.

In practical applications, the degassing chamber described above may have the following problems.

First, since the initial temperature of the current degassing process is higher than the initial temperature of the previous degassing process, that is, the initial temperature of the degassing chamber gradually increases as the number of processes increases (i.e., the initial temperature of the degassing chamber gradually increases as more and more degassing processes are performed). As such, when different batches of substrates successively enter the same degassing chamber in a certain order, there is a difference in the initial temperature of the housing for different batches of substrates. Therefore, under the condition that the heating time is the same, the substrates in different batches eventually reach different temperatures, which leads to inconsistent quality for the substrates of different batches.

Second, since the substrate temperature in the central region of the housing tends to be higher than the substrate temperature in the edge region of the housing when a bulb is used to heat the substrates, that is, the temperature uniformity of the same batch of substrates is poor. As such, the quality of the same batch of substrates may be inconsistent.

Third, although the multiple-substrate degassing chamber can heat a plurality of substrates simultaneously, because the latter batch of substrates can only enter the housing until the previous batch of substrates in the housing are heated and transferred out from the housing, increasing the number of substrates in a same batch alone may not be able to significantly increase the productivity of the equipment. Although it is possible to increase the productivity by arranging two or more degassing chambers, it will also result in increased complexity and cost of the equipment.

### BRIEF SUMMARY OF THE DISCLOSURE

One aspect of the present disclosure provides a degassing method, including: heating the degassing chamber to provide the internal temperature at a preset temperature and maintaining the internal temperature of the degassing chamber at the preset temperature; and transferring substrates to be degassed into the degassing chamber and heating the substrates for a preset period of time, and taking the substrates out after the preset period of time of the heating.

Another aspect of the present disclosure provides a degassing chamber, including: a temperature controller, configured to heat a degassing chamber to provide an internal temperature at a preset temperature and to maintain the internal temperature of the degassing chamber at the preset temperature; and a transfer controller, configured to control a manipulator to transfer substrates to be degassed into the degassing chamber to heat the substrates for a preset period of time and take the substrates out after the preset period of time.

Another aspect of the present disclosure provides a semiconductor processing apparatus. The semiconductor processing apparatus includes a degassing chamber. The degassing chamber includes a temperature controller, configured to heat a degassing chamber to provide an internal temperature at a preset temperature and to maintain the internal temperature of the degassing chamber at the preset temperature; and a transfer controller, configured to control a manipulator to transfer substrates to be degassed into the degassing chamber to heat the substrates for a preset period of time and take the substrates out after the preset period of time.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic process flow of a PVD process for fabricating copper interconnections;

FIG. 2 illustrates a flowchart of an exemplary degassing method according to some embodiments of the present disclosure;

FIG. 3 illustrates a schematic structural view of an exemplary degassing chamber according to some embodiments of the present disclosure; and

FIG. 4 illustrates a schematic top view of the degassing chamber shown in FIG. 3.

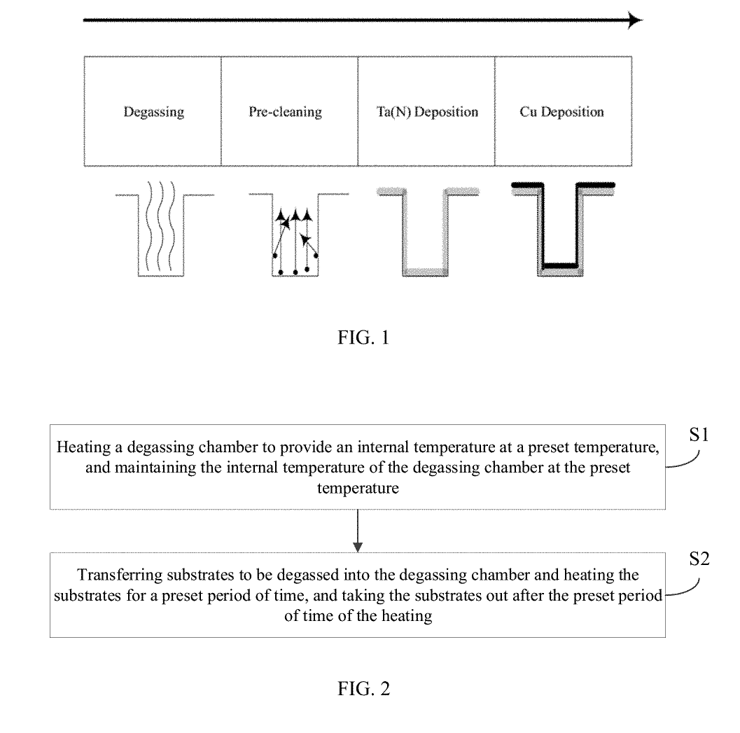

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

The present disclosure provides a degassing method, a degassing chamber, and a semiconductor processing apparatus. The disclosed degassing method, degassing chamber, and semiconductor processing apparatus may be able to improve the temperature uniformity not only for a same batch of substrates but also for different batches of substrates. In addition, the disclosed degassing method, degassing chamber, and semiconductor processing apparatus may also be able to realize anytime loading/unloading of the substrates to be degassed, thereby increasing the productivity of the equipment.

The present disclosure provides a degassing method. FIG. 2 illustrates a flowchart of an exemplary degassing method according to an embodiment of the present disclosure. Referring to FIG. 2, the degassing method may include:

step S1, heating the degassing chamber to provide the internal temperature at a preset temperature and maintaining the internal temperature of the degassing chamber at the preset temperature; and

step S2, transferring substrates to be degassed into the degassing chamber and heating the substrates for a preset period of time, and taking the substrates out after the preset period of time of the heating.

In one embodiment, step S1 may allow the degassing chamber to be maintained at a constant temperature such that the substrates entering the degassing chamber can be heated at a constant temperature. As such, the problem that different batches of substrates eventually reach different temperatures due to the difference in initial chamber temperature may be avoided, and thus the quality consistency of different batches of substrates can be improved. Step S2 may be able to realize anytime instant loading/unloading of the substrates to be degassed. That is, any number of substrates to be degassed can be introduced into the degassing chamber at any time, and taken out after a certain period of heating. As such, the process for degassing the next batch of substrates can be carried out without waiting for all the substrates in the housing to be heated and transferred out from the housing. Therefore, the productivity of the equipment may be improved. At the same time, by taking the substrates to be degassed out after a certain period of heating, the substrates entering the housing at any time can all be ensured to reach the preset target temperature, and thus precise control of the substrate temperature can be achieved.

In practical applications, the heating time for the substrates in step S2 may be determined according to the specific case. As long as the substrate can eventually reach the same target temperature, any appropriate heating time may be adopted. In addition, a program may be used to control the manipulator to transfer the substrates, such that the substrates can be taken out after being heated for a certain period of time.

In one embodiment, step S1 may include:

step S11, heating the degassing chamber to provide the internal temperature at the preset temperature; and

step S12, detecting the internal temperature of the degassing chamber in real time, comparing the internal temperature with the preset temperature, and controlling the internal temperature of the degassing chamber according to the comparison result to maintain the internal temperature of the degassing chamber at the preset temperature.

In step S12, when the difference between the internal temperature and the preset temperature is outside an allowable temperature range, the internal temperature of the degassing chamber may be increased or decreased until the internal temperature and the preset temperature tend to be consistent with each other, and thus the internal temperature of the degassing chamber may be maintained at the preset temperature.

By detecting the internal temperature of the degassing chamber in real time and adjusting the internal temperature of the degassing chamber according to the internal temperature and the preset temperature, closed-loop control of temperature adjustment can be implemented. Therefore, the internal temperature of the degassing chamber can be precisely controlled.

Since the degassing chamber heats the substrates to be degassed at a constant temperature, the difference between the target temperature of the substrates to be degassed and the preset temperature may have a fixed value. Therefore, when the target temperature of the substrates to be degassed is known, the above preset temperature can then be determined. For example, when the preset temperature is 130° C., the substrates to be degassed reach a target temperature of 160° C. after being heated for a certain period of time. In this case, when the substrates to be degassed need to be heated to 160° C., the preset temperature may need to be set to 130° C.

The present disclosure also provides a degassing chamber. The degassing chamber may include a temperature controller and a transfer controller. The temperature controller may be configured to heat a degassing chamber to provide an internal temperature at a preset temperature and to maintain the internal temperature of the degassing chamber at the preset temperature. The transfer controller may be configured to control a manipulator to transfer substrates to be degassed into the degassing chamber to heat the substrates for a preset period of time and take the substrates out after the preset period of time. In one embodiment, the transfer controller may be an upper computer, or any appropriate unit or device that can directly issue control commands.

By using the temperature controller to heat the degassing chamber, the internal temperature may be able to reach a preset temperature and then remain unchanged at the preset temperature. As such, the problem that different batches of substrates eventually reach different temperatures due to the difference in the initial temperature of the housing can be avoided, and thus the quality consistency of different batches of substrates can be improved. By using the transfer controller to control a manipulator to transfer the substrates to be degassed into the degassing chamber and take the substrates out after a certain period of heating, anytime instant loading/unloading of the substrates to be degassed may be realized. That is, any number of substrates to be degassed can be introduced into the degassing chamber at any time, and taken out after a certain period of heating. As such, the process for degassing the next batch of substrates can be carried out without waiting for the previous batch of the substrates to be heated and transferred out from the housing. Therefore, the productivity of the equipment may be improved. At the same time, by taking the substrates to be degassed out after a certain period of heating, the substrates entering the housing at any time can all be ensured to reach the preset target temperature, and thus precise control of the substrate temperature can be achieved.

In one embodiment, the temperature controller may include a heating component, a temperature measuring component, and a temperature-difference controller. The heating component may be configured to heat the degassing chamber to provide the internal temperature at the preset temperature. The temperature measuring component may be configured to detect the internal temperature of the degassing chamber in real time. The temperature measuring component may include a thermocouple, an infrared sensor, or any other temperature monitoring mechanism. The temperature-difference controller may be configured to compare the internal temperature with the preset temperature, and then control the heating component according to the comparison result to maintain the internal temperature of the degassing chamber at the preset temperature.

For example, the temperature-difference controller may determine whether the difference between the internal temperature and the preset temperature exceeds an allowable temperature range, and when the difference between the internal temperature and the preset temperature exceeds the allowable temperature range, the internal temperature of the degassing chamber may be increased or decreased until the internal temperature and the preset temperature tend to be consistent with each other, and thus the internal temperature of the degassing chamber may be maintained at a preset temperature. By detecting the internal temperature of the degassing chamber in real time using the temperature measuring component, and adjusting the internal temperature of the degassing chamber according to the internal temperature and the preset temperature using the temperature-difference controller, closed-loop control of temperature adjustment can be implemented. Therefore, the internal temperature of the degassing chamber can be precisely controlled.

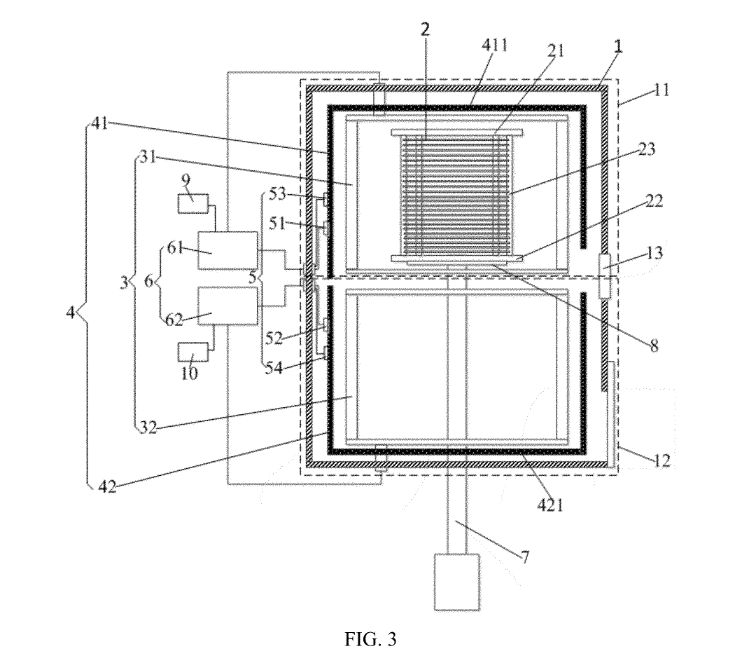

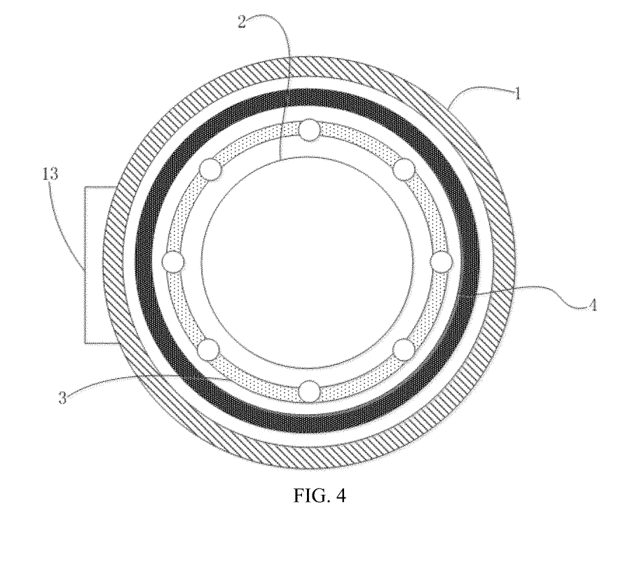

In the following, examples of the degassing chamber provided by various embodiments according to the present disclosure will be described in detail. For example, referring to FIGS. 3 and 4, the degassing chamber may further include a housing 1 and a substrate container 2 for carrying the substrates to be degassed. The housing 1 may define a heating space for the degassing chamber. A substrate transferring opening 13 may be formed in the sidewall of the housing 1, and the substrate transferring opening 13 may provide a path for transferring the substrates into or out from the housing 1. The substrate container 2 may include a base 23, a top cover 21, and a bottom cover 22. The base 23 may be provided with a plurality of slots for placing a plurality of substrates. In addition, the arrangement of the base 23 must take the transferability of the substrates into consideration to prevent the substrates from colliding with the base 23 when the substrates are transferred by the manipulator. The top cover 21 and the bottom cover 22 may be respectively disposed at opposite ends of the base 23 with the top cover 21 opposed to the top of the housing 1 while the bottom cover 22 opposed to the bottom of the housing 1. The base 23 may be used to support the top cover 21, the bottom cover 22, and the substrates located thereon. The substrate container 2 may be made of an aluminum material (including aluminum metal and aluminum-containing alloy), or any other appropriate material that is capable for vacuum and high-temperature application. The presence of the top cover 21 and the bottom cover 22 may allow the substrates located at the upper and the lower ends of the substrate container 2 to be exposed by irradiation of the bulb, and thus be heated properly. Therefore, the temperature difference between the substrates in the center region of the substrate container 2 and the substrates in the upper-end and the lower-end regions may be reduced.

The heating component 3 may include a first light source component 31 and a second light source component 32. The housing 1 may be divided into a first chamber 11 and a second chamber 12 by a substrate transferring opening 11. The first light source component 31 may be located inside the first chamber 11, and the second light source component 32 may be located inside the second chamber 12. The first light source component 31 and the second light source component 32 may be used to heat the substrates in the substrate container 2. Therefore, regardless whether the substrate in the substrate container 2 is in a region above the substrate transferring opening 11 or in a region below the substrate transferring opening 11, the substrate can always be heated by the light source component, thereby ensuring that the process temperature of the substrates is uniform during the degassing process and the substrate loading/unloading process. As such, not only the quality of the degassing process for the substrates is improved, but also the substrate provided for subsequent processes is cleaner.

In one embodiment, the first light source component 31 may be disposed around the first chamber 11 along the circumferential direction of the first chamber 11 and inside the inner sidewall of the first chamber 11; the second light source component 32 may be disposed around the second chamber 12 along the circumferential direction of the second chamber 12 and inside the inner sidewall of the second chamber 12.

For example, the first light source component 31 and the second light source component 32 may be disposed in the housing 1 and separated from each other along a vertical direction. The first light source component 31 and the second light source component 32 may be symmetrically arranged with respect to the substrate transferring opening 11. The substrate container 2 can be vertically movable in a space surrounded by the first light source component 31 and the second light source component 32. As such, regardless of the position that the substrate container 2 moves to in the housing 1, the substrates in the substrate container 2 can be uniformly heated by the first light source component 31 and/or the second light source component 32. Therefore, when substrates need to be introduced into or taken out from the housing 1, even when the position of the substrate container 2 in the first chamber and the second chamber 12 is changed, the substrates in the substrate container 2 can still be heated by the first light source component 31 and/or the second light source component 32.

Since the first light source component 31 or the second light source component 32 has a cylinder shape to form the heating space, each of them may surround the substrate container 2 and may uniformly heat the substrates in the substrate container 2, and thus the temperature uniformity of the substrates in the substrate container 2 may be improved. Of course, in practical applications, the first light source component or the second light source component may adopt any other structure as long as the first light source component or the second light source component can heat the substrates in the substrate container.

In one embodiment, the temperature measuring component 5 may obtain the internal temperature of the degassing chamber by detecting the temperature of the substrate container 2. That is, the temperature of the substrate container 2 may be regarded as the internal temperature of the degassing chamber. The temperature of the substrate container 2 can reflect the internal temperature of the degassing chamber more precisely, thereby improving the accuracy of the detection. Alternatively, a detecting substrate (a pseudo substrate) may be disposed on the substrate container 2, and the temperature measuring component 5 may obtain the internal temperature of the degassing chamber by detecting the temperature of the detecting substrate. That is, the temperature of the detecting substrate may be regarded as the internal temperature of the degassing chamber. The temperature of the detecting substrate can also precisely reflect the internal temperature of the degassing chamber, thereby improving the accuracy of the detection.

In one embodiment, the heating component 3 may further include a first reflection tube 41 and a second reflection tube 42. The first reflection tube 41 may be located between the first chamber 11 and the first light source component 31; and the second reflection tube 42 may be located between the second chamber 12 and the second light source component 32. The first reflection tube 41 and the second reflection tube 42 may be configured to respectively reflect the light irradiated thereon toward the substrate container 2 and the substrates in the substrate container 2, that is, the first reflection tube 41 and the second reflection tube 42 may be used to respectively reflect the heat transferred to them back to the substrate container 2 and the substrates in the substrate container 2. For example, the first reflection tube 41 may have a cylindrical structure that is closed in the circumferential direction. The first reflection tube 41 may be disposed between the first light source component 31 and the first chamber 11 and may surround the first light source component 31 in the circumferential direction of the first light source component 31. The second reflection tube 42 may have a cylindrical structure that is closed in the circumferential direction. The second reflection tube 42 may be disposed between the second light source component 32 and the second chamber 12 and may surround the second light source component 32 in the circumferential direction of the second light source component 32. Through such an arrangement, the heat generated by the first light source component 31 and the second light source component 32 can be held in the tube as desired. As such, the heat utilization rate of the first light source component 31 and the second light source component 32 may be improved, the heating efficiency may be improved, and at the same time, the heating temperatures in the first reflection tube 41 and the second reflection tube 42 may be balanced, such that the substrates in the substrate container 2 can be uniformly heated.

The first reflection tube 4 may include a top plate 411, and the second reflection tube 42 may include a bottom plate 421. The top plate 411 may cover one end of the first reflection tube 41 that is away from the substrate transferring opening 13; and the bottom plate 421 may cover one end of the second reflection tube 42 that is away from the substrate transferring opening 13. The top plate 411 and the bottom plate 421 may be used to respectively reflect the light irradiated thereon toward the substrates to be degassed in the housing 1. The arrangement of the top plate 411 and the bottom plate 421 may enable the reflection tubes 4 disposed in the housing 1 to form a closed heating space, thereby ensuring a desired effect of maintaining the preset temperature in the housing 1.

In one embodiment, by polishing and/or surface-treating the inner sidewalls of the first reflection tube 41 and the second reflection tube 42, the light irradiated thereon can be diffusely reflected and/or specularly reflected. The diffuse reflection may be able to make the light emitted by the first light source component 31 and the second light source component 32 uniform in the tubes and also uniform in the reflection, such that the heating energy in the tube may be more uniform. The specular reflection may cause most of the light emitted by the first light source component 31 and the second light source component 32 to be reflected back into the tube, thereby reducing the loss of heating energy and ensuring the heat balance in the tube.

In one embodiment, by disposing the first reflection tube 41 between the first chamber 11 and the first light source component 31, and the second reflection tube 42 between the second chamber 12 and the second light source component 32, the first light source component 31 and the second light source component 32 can be separated from the sidewall of the first chamber 11 and the sidewall of the second chamber 12, respectively. Further, due to the above structure and material of the first reflection tube 41 and the second reflection tube 42, a nearly closed and constant high temperature environment may be formed in each of the first chamber 11 and the second chamber 12. Under the constant high temperature environment, heat absorption and heat dissipation of various components in the first chamber 11 and in the second chamber 12 can be balanced. When a substrate is transferred into the housing 1, the heat capacity of a single substrate may be much smaller than the heat capacity of the entire chamber 1. Therefore, every component in the housing 1 may serve as a heat source for the substrate, such that the substrate will quickly reach thermal equilibrium under the heat radiation of the first reflection tube 41, the second reflection tube 42, the first light source component 31, and the second light source component 32.

The temperature measuring component 5 may include a first temperature measuring element 51 and a second temperature measuring element 52. The first temperature measuring element 51 may be configured to obtain the internal temperature of the first chamber 11 by detecting the temperature of the first reflection tube 41; and the second temperature measuring element 52 may be configured to obtain the internal temperature of the second chamber 12 by detecting the temperature of the second reflection tube 42. Correspondingly, the temperature-difference controller 6 may include a first temperature controller 61 and a second temperature controller 62. The first temperature controller 61 may be configured to receive the internal temperature of the first chamber 11 sent by the first temperature measuring element 51, and compare the internal temperature with the preset temperature. The first temperature controller 61 may be further configured to control the first light source component 31 according to the comparison result to maintain the internal temperature of the first chamber 11 at the preset temperature. The second temperature controller 62 may be configured to receive the internal temperature of the second chamber 12 sent by the second temperature measuring element 52, and compare the internal temperature with the preset temperature. The second temperature controller 62 may be further configured to control the second light source component according to the comparison result to maintain the internal temperature of the second chamber 12 at the preset temperature. As such, closed-loop control of temperature adjustment of the first chamber 11 and the second chamber 12 can be implemented separately. Therefore, precise control of the internal temperature can be respectively achieved for the first chamber 11 and the second chamber 12.

In one embodiment, the temperature measuring component 5 may further include a first backup component 53 and a second backup component 54. The first backup component 53 may be configured to detect the temperature of the first reflection tube 41 and feed the temperature back to the first temperature controller 61; and the second backup component 54 may be configured to detect the temperature of the second reflection tube 42 and feed the temperature back to the second temperature controller 62. Correspondingly, the first temperature controller 61 may be further configured to determine whether the difference between the temperature of the first reflective 41 sent by the first temperature measuring element 51 and the temperature of the first reflective 41 sent by the first backup component 53 is within a preset range; the second temperature control member 62 may also be configured to determine whether the difference between the temperature of the second reflector 42 sent by the second temperature measuring element 52 and the temperature of the second reflector 42 sent by the second backup component 54 is within a preset range. With the first backup component 53 and the second backup component 54, whether the working statuses of the first temperature measuring element 51 and the second temperature measuring element 52 are normal can be separately monitored, thereby preventing the first temperature controller 61 and the second temperature controller 62 from obtaining incorrect temperature feedbacks due to accidental damages of the first temperature measuring element 51 and the second temperature measuring element 52.

Further, in one embodiment, the degassing chamber may also include a first alarm element 9 and a second alarm element 10. When it is determined that the difference in the temperature of the first reflection tube 41 is out of the preset range, the first temperature controller 61 may be configured to control the first alarm element 9 to send an alarm; and when it is determined that the difference in the temperature of the second reflection tube 42 is out of the preset range, the second temperature controller 62 may be configured to control the second alarm element 10 to send an alarm. Through the first alarm element 9 and the second alarm element 10, it is possible to know in time that the temperature control is abnormal.

It should be noted that, in one embodiment, the first temperature measuring element 51 and the second temperature measuring element 52 are both thermocouples, and the two thermocouples are mounted on the first reflection tube 41 and the second reflection tube 42, respectively and perform measurements in a contact manner. However, the present disclosure is not limited to the specific example described above, and in practical applications, the first temperature measuring element 51 and the second temperature measuring element 52 may also be able to perform measurements in a non-contact manner, such as using an infrared sensor. When performing measurements using an infrared sensor, it may only requires to align the measuring surface of the infrared sensor with the reflection tube, and adjust the distance between the measuring surface of the infrared sensor and the reflection tube to be within the measuring range of the infrared sensor.

In addition, the degassing chamber may further include a lifting system 7. The lifting system 7 may penetrate the bottom of the housing 1 and may be connected to the bottom cover 22 of the substrate container 2. The lifting system 7 may be configured to drive the substrate container 2 to be lifted and lowered such that substrates placed at different height positions in the substrate container 2 can be moved to the height position corresponding to the substrate transferring opening 13 for substrate loading/unloading. Further, a thermal insulation 8 may be disposed at the joint position of the lifting system 7 and the bottom cover 22 to isolate heat conduction between the substrate container 2 and the lifting system 7.

In one embodiment, the degassing process of the above degassing chamber may be the following. Prior to heating the substrates to be degassed, under the control of the temperature-difference controller 6, the heating component 3 may output a large power to quickly heat the housing 1 to a preset temperature. When the temperature of the internal components of the housing 1 reaches the preset temperature, under the control of the temperature-difference controller 6, the heating component 3 may output a lower power to maintain the temperature in the housing 1 at the constant preset temperature. When the degassing process starts, one or more substrates may be loaded through the substrate transferring opening 13, and the substrates may be placed at different height positions in the substrate container 2 by moving the lifting system 7. Driven by the lifting system 7, the substrate container 2 may be moved to the degassing process position that is adjacent to the heating component 3. After the substrates reach the preset target temperature, the lifting system 7 may drive the substrate container 2 to move to the height position corresponding to the substrate transferring opening 13, and the substrates may then be taken out by the manipulator. Further, substrates may be replenished to the substrate container 2; and the above process of loading/unloading the substrates may be repeated until the degassing process is completed for all the substrates to be degassed.

Further, the present disclosure also provides a semiconductor processing apparatus. The semiconductor processing apparatus may include a degassing chamber consistent various embodiments of the present disclosure.

The semiconductor processing apparatus provided by the embodiments of the present disclosure can improve the temperature uniformity of the substrates in the same batch as well as in different batches by using the above-mentioned degassing chamber according to the embodiments of the present disclosure. In addition, the semiconductor processing apparatus may also be able to realize anytime instant loading/unloading of the substrates to be degassed, thereby increasing the productivity of the equipment.

Compared to conventional degassing method, degassing chamber, and semiconductor processing apparatus for degassing process, the disclosed degassing method, degassing chamber, and semiconductor processing apparatus may demonstrate the following advantages.

According to the disclosed degassing method, degassing chamber, and semiconductor processing apparatus, the degassing chamber is heated such that the internal temperature of the degassing chamber reaches a preset temperature. The internal temperature of the degassing chamber is then maintained at the preset temperature. Further, substrates to be degassed are transferred into the degassing chamber for constant-temperature heating, and then taken out after a certain period of heating. By maintaining the internal temperature of the degassing chamber at the preset temperature, the problem that different batches of substrates eventually reach different temperatures due to the difference in the initial temperature of the housing can be avoided, and thus the quality consistency of different batches of substrates can be improved. By taking the substrates to be degassed out after a certain period of heating at a constant temperature, anytime instant loading/unloading of the substrates to be degassed can be realized. That is, any number of substrates to be degassed can be introduced into the degassing chamber at any time, and taken out after a certain period of heating. As such, the process for degassing the next batch of substrates can be carried out without waiting for all the substrates in the housing to be heated and transferred out from the housing. Therefore, the productivity of the equipment may be improved. Moreover, by taking the substrates to be degassed out after a certain period of heating at a constant temperature, the substrates entering the housing at any time can all be ensured to reach the preset target temperature, and thus precise control of the substrate temperature can be achieved.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A degassing method, comprising:
heating a degassing chamber to provide an internal temperature at a preset temperature, and maintaining the internal temperature of the degassing chamber at the preset temperature; and
transferring substrates to be degassed into the degassing chamber and heating the substrates for a preset period of time, and taking the substrates out after the preset period of time of the heating.

2. The degassing method according to claim 1, wherein maintaining the internal temperature of the degassing chamber at the preset temperature includes:
after heating the degassing chamber to provide the internal temperature at the preset temperature,
detecting the internal temperature of the degassing chamber in real time,
comparing the internal temperature with the preset temperature, and
controlling the internal temperature of the degassing chamber according to a comparison result to maintain the internal temperature of the degassing chamber at the preset temperature.

3. A degassing chamber, comprising:
a temperature controller, configured to heat a degassing chamber to provide an internal temperature at a preset temperature and to maintain the internal temperature of the degassing chamber at the preset temperature; and
a transfer controller, configured to control a manipulator to transfer substrates to be degassed into the degassing chamber to heat the substrates for a preset period of time and take the substrates out after the preset period of time.

4. The degassing chamber according to claim 3, wherein the temperature controller includes:
a heating component, configured to heat the degassing chamber to provide the internal temperature at the preset temperature;
a temperature measuring component, configured to detect the internal temperature of the degassing chamber in real time; and
a temperature-difference controller, configured to compare the internal temperature of the degassing chamber with the preset temperature, and control the heating component according to a comparison result to maintain the internal temperature of the degassing chamber at the preset temperature.

5. The degassing chamber according to claim 4, further including:
a housing and a substrate container for carrying the substrates to be degassed, wherein:
a substrate transferring opening is formed on a sidewall of the housing, and the substrate transferring opening provides a path for transferring the substrates into or out from the housing;
the substrate container is movable in the housing along a vertical direction;
the heating component includes a first light source component and a second light source component; and
the housing is divided into a first chamber and a second chamber by the substrate transferring opening, wherein:
the first light source component is located inside the first chamber,
the second light source component is located inside the second chamber, and
the first light source component and the second light source component are configured to heat the substrates to be degassed located in the substrate container.

6. The degassing chamber according to claim 5, wherein:
the temperature measuring component is configured to obtain the internal temperature of the degassing chamber by detecting a temperature of the substrate container.

7. The degassing chamber according to claim 5, wherein:
a detecting substrate is disposed on the substrate container, and:
the temperature measuring component is configured to obtain the internal temperature of the degassing chamber by detecting a temperature of the detecting substrate.

8. The degassing chamber according to claim 5, wherein:
the heating component includes a first reflection tube and a second reflection tube, wherein:
the first reflection tube is located between a sidewall of the first chamber and the first light source component, and the second reflection tube is located between a sidewall of the second chamber and the second light source component; and
the first reflection tube and the second reflection tube are configured to reflect light irradiated thereon toward the substrates to be degassed in the substrate container.

9. The degassing chamber according to claim 8, wherein:
the first reflection tube includes a top plate, the second reflection tube includes a bottom plate, wherein:
the top plate covers an end of the first reflection tube that is away from the substrate transferring opening, and the bottom plate covers an end of the second reflection tube that is away from the substrate transferring opening, and
the top plate and the bottom plate are used to reflect light irradiated thereon toward the substrates to be degassed in the housing.

10. The degassing chamber according to claim 8, wherein:
the temperature measuring component includes a first temperature measuring element and a second temperature measuring element, wherein:
the first temperature measuring element is configured to obtain an internal temperature of the first chamber by detecting a temperature of the first reflection tube, and
the second temperature measuring element is configured to obtain an internal temperature of the second chamber by detecting a temperature of the second reflection tube;
the temperature-difference controller includes a first temperature controller and a second temperature controller, wherein:
the first temperature controller is configured to receive the internal temperature of the first chamber sent by the first temperature measuring element, compare the internal temperature of the first chamber with the preset temperature, and control the first light source component according to a comparison result to maintain the internal temperature of the first chamber at the preset temperature, and
the second temperature controller is configured to receive the internal temperature of the second chamber sent by the second temperature measuring element, compare the internal temperature of the second chamber with the preset temperature, and control the second light source component according to a comparison result to maintain the internal temperature of the second chamber at the preset temperature.

11. The degassing chamber according to claim 10, wherein:
the temperature measuring component further includes a first backup component and a second backup component, wherein:
the first backup component is configured to detect a temperature of the first reflection tube, and the second backup component is configured to detect a temperature of the second reflection tube; and
the first temperature controller is further configured to determine whether a difference between the temperature of the first reflection tube sent by the first temperature measuring element and the temperature of the first reflection tube sent by the first backup component is within a preset range; and the second temperature controller is further configured to determine whether a difference between the temperature of the second reflection tube sent by the second temperature measuring element and the temperature of the second reflection tube respectively sent by the second backup component is within a preset range.

12. The degassing chamber according to claim 11, further including a first alarm element and a second alarm element, wherein:
the first temperature controller is configured to control the first alarm element to send an alarm when determining that the difference between the temperature of the first reflection tube sent by the first temperature measuring element and the temperature of the first reflection tube sent by the first backup component is out of the preset range; and
the second temperature controller is configured to control the second alarm element to send an alarm when determining that the difference between the temperature of the second reflection tube sent by the second temperature measuring element and the temperature of the second reflection tube sent by the second backup component is out of the preset range.

13. The degassing chamber according to claim 4, wherein:
the temperature measuring component includes a thermocouple or an infrared sensor.

14. A semiconductor processing apparatus, comprising:
a degassing chamber, comprising:
a temperature controller, configured to heat a degassing chamber to provide an internal temperature at a preset temperature and to maintain the internal temperature of the degassing chamber at the preset temperature; and
a transfer controller, configured to control a manipulator to transfer substrates to be degassed into the degassing chamber to heat the substrates for a preset period of time and take the substrates out after the preset period of time.

15. The semiconductor processing apparatus according to claim 14, wherein the temperature controller includes:
a heating component, configured to heat the degassing chamber to provide the internal temperature at the preset temperature;
a temperature measuring component, configured to detect the internal temperature of the degassing chamber in real time; and
a temperature-difference controller, configured to compare the internal temperature of the degassing chamber with the preset temperature, and control the heating component according to a comparison result to maintain the internal temperature of the degassing chamber at the preset temperature.

16. The semiconductor processing apparatus according to claim 15, further including:
a housing and a substrate container for carrying the substrates to be degassed, wherein:
a substrate transferring opening is formed on a sidewall of the housing, and the substrate transferring opening provides a path for transferring the substrates into or out from the housing;
the substrate container is movable in the housing along a vertical direction;
the heating component includes a first light source component and a second light source component; and
the housing is divided into a first chamber and a second chamber by the substrate transferring opening, wherein:
the first light source component is located inside the first chamber,
the second light source component is located inside the second chamber, and
the first light source component and the second light source component are configured to heat the substrates to be degassed located in the substrate container.

17. The semiconductor processing apparatus according to claim 16, wherein:
a detecting substrate is disposed on the substrate container, and:
the temperature measuring component is configured to obtain the internal temperature of the degassing chamber by detecting a temperature of the detecting substrate.

18. The semiconductor processing apparatus according to claim 16, wherein:
the heating component includes a first reflection tube and a second reflection tube, wherein:
the first reflection tube is located between a sidewall of the first chamber and the first light source component, and the second reflection tube is located between a sidewall of the second chamber and the second light source component;
the first reflection tube and the second reflection tube are configured to reflect light irradiated thereon toward the substrates to be degassed in the substrate container; and
the first reflection tube includes a top plate, the second reflection tube includes a bottom plate, wherein:
the top plate covers an end of the first reflection tube that is away from the substrate transferring opening, and the bottom plate covers an end of the second reflection tube that is away from the substrate transferring opening, and
the top plate and the bottom plate are used to reflect light irradiated thereon toward the substrates to be degassed in the housing.

19. The semiconductor processing apparatus according to claim 18, wherein:
the temperature measuring component includes a first temperature measuring element and a second temperature measuring element, wherein:
the first temperature measuring element is configured to obtain an internal temperature of the first chamber by detecting a temperature of the first reflection tube, and
the second temperature measuring element is configured to obtain an internal temperature of the second chamber by detecting a temperature of the second reflection tube;
the temperature-difference controller includes a first temperature controller and a second temperature controller, wherein:
the first temperature controller is configured to receive the internal temperature of the first chamber sent by the first temperature measuring element, compare the internal temperature of the first chamber with the preset temperature, and control the first light source component according to a comparison result to maintain the internal temperature of the first chamber at the preset temperature, and
the second temperature controller is configured to receive the internal temperature of the second chamber sent by the second temperature measuring element, compare the internal temperature of the second chamber with the preset temperature, and control the second light source component according to a comparison result to maintain the internal temperature of the second chamber at the preset temperature.

20. The semiconductor processing apparatus according to claim 19, wherein:
the temperature measuring component further includes a first backup component and a second backup component, wherein:
the first backup component is configured to detect a temperature of the first reflection tube, and the second backup component is configured to detect a temperature of the second reflection tube; and
the first temperature controller is further configured to determine whether a difference between the temperature of the first reflection tube sent by the first temperature measuring element and the temperature of the first reflection tube sent by the first backup component is within a preset range; and the second temperature controller is further configured to determine whether a difference between the temperature of the second reflection tube sent by the second temperature measuring element and the temperature of the second reflection tube respectively sent by the second backup component is within a preset range.
